(19) United States
(12) Patent Application Publication
(10) Pub. No.: US 2006/0202001 A1
(43) Pub. Date: Sep. 14, 2006

(54) ENHANCED HEAT SYSTEM FOR BGA/CGA REWORK

(75) Inventors: Raymond D. Birchall, Highland, NY (US); Brian D. Chapman, Poughkeepsie, NY (US); Wai Mon Ma, Poughkeepsie, NY (US); James J. Petrone, Hyde Park, NY (US); Nandakumar N. Ranadive, Wappinger Falls, NY (US)

Correspondence Address: FREDERICK W. GIBB, III;GIBB INTELLECTUAL PROPERTY LAW FIRM, LLC, 2568-A RIVA ROAD, SUITE 304, ANNAPOLIS, MD, 21401, US

(73) Assignee: INTERNATIONAL BUSINESS MACHINES CORPORATION, Armonk, NY (US)

(21) Appl. No.: 10/906,824

(22) Filed: Mar. 8, 2005

(51) Int. Cl. H02H 7/00; B23K 1/018; H05K 7/06

(52) U.S. Cl. 228/264; 361/19

(57) ABSTRACT

A method and system for heating a circuit board component to an approximately uniform temperature sufficient to reflow the connections between the circuit board component and the circuit board. The method and system include a supplemental gas heater having a diffuser plate. The circuit board is placed against the diffuser plate and heated gas is channeled through openings in the diffuser plate into vias in the circuit board to heat a circuit board component connected on the opposite side of the circuit board. Heated gas can be channeled through selected vias towards predetermined areas and/or specified connections such as towards those areas or connections where there is a temperature differential greater than approximately 10 degrees Celsius compared to other areas or connections across the circuit board component. Hot gas can be channeled through selected vias by baffling or patterning the diffuser plate, accordingly.

### BACKGROUND OF THE INVENTION

1. Field of the Invention

The invention relates generally to a method and system for reworking circuit boards and, more particularly, to a method and system for heating a circuit board component to an approximately uniform temperature sufficient to reflow the connections between the circuit board component and the circuit board.

2. Description of the Related Art

The surface mount technology (SMT) industry is trending towards increased usage of ball grid array (BGA) and ceramic column grid array (CCGA) packages (i.e., circuit boards). During a reflow process of a circuit board component, it is essential to maintain the thermal gradient between various circuit board components on the circuit board within specified limits. This is to ensure that the solder joints of only the particular component are melted. For standard eutectic tin-lead (Sn—Pb) solder, this maximum differential between components is established at 20 degrees Celsius. For lead-free solders, the maximum temperature differential drops down to about 10 degrees Celsius. This is due to the higher melting temperature of the lead-free solder which increases the thermal stress level within the circuit board. BGA or CCGA circuit boards are often reworked by globally heating the entire circuit board and then locally heating the individual circuit board component with hot gas (e.g., air, nitrogen, etc.) and/or heating elements in order to reach the reflow temperature at the solder joints. As the individual circuit board component is heated, the temperature distribution across the x, y and z axes of the component should also remain essentially uniform (e.g., within the 10 degrees Celsius). Maintaining a uniform temperature distribution minimizes distortion within the circuit board component and the circuit board. However, establishing and maintaining uniformity of temperature distribution can be difficult. It would be desirable to provide an improved method and system for reworking a circuit board that is able to efficiently establish and maintain a uniform temperature distribution across a circuit board component.

### SUMMARY OF THE INVENTION

The present invention is a method and system for reworking circuit boards. Specifically, it is a method and system for heating a circuit board component to an approximately uniform temperature sufficient to reflow the connections between the circuit board component and the circuit board.

An embodiment of the system of the present invention for reworking a circuit board can comprise three heaters. The first heater is positioned over the first side of a circuit board and channels a flow of hot gas directly over a circuit board component connected to the first side of the circuit board. The second heater is positioned on the second side of the circuit board, opposite the circuit board component, and channels a flow of hot gas towards vias in the circuit board to conduct heat through the vias and to thereby heat the circuit board component from the second side of the circuit board. The third heater pre-heats the entire circuit board.

More particularly, the second heater comprises a gas heating device that heats a gas to a predetermined temperature sufficient to reflow connections between the circuit board component and the circuit board. The heated gas is channeled through a gas conduit into a nozzle via a gas inlet on the sidewall of the nozzle. The nozzle further comprises a flat supporting base and additional sidewalls. The nozzle is connected to a diffuser plate opposite the flat base. When in operation, the diffuser plate is positioned against the second side of the circuit board opposite the circuit board component that is connected on the first side of the circuit board. The diffuser plate comprises openings corresponding to vias on the circuit board. Vias are conductor-filled channels through the circuit board. Each via channel has opposing apertures on the first and second side of the circuit board. The apertures located on the first side of the circuit board are adjacent to the circuit board component and, specifically, to connections between the circuit board component and the circuit board. A flow of heated gas entering the nozzle is channeled through the diffuser plate openings towards the vias. The conductors in the vias are heated and, thus, direct heat towards the circuit board component. The number and pattern of diffuser plate openings can be changed to correspond with a number and pattern of selected vias. The selected vias can be vias having apertures adjacent to predetermined areas of the circuit board component or specific connections between the circuit board and the circuit board component. For example, the predetermined areas or specific connections can be those areas or connections where there is a temperature differential greater than approximately 10 degrees Celsius compared to other areas or connections across the circuit board component. Heated gas channeled through the diffuser plate openings towards the selected vias can heat the selected vias and, thus, conduct heat towards the predetermined areas or the specific connections on the circuit board component to control temperature distribution across the circuit board component. The nozzle can also be configured to receive interchangeable diffuser plates. These interchangeable diffuser plates can comprise different numbers of openings and/or different patterns of openings corresponding to selected vias. An additional feature of the system can be a baffle connected to the diffuser plate in order to regulate the flow of the heated gas towards the selected vias.

An embodiment of a method of the present invention for reworking a circuit board can comprise three heating method processes. A circuit board can be pre-heated. A circuit board component that is connected to a first side of the circuit board can be heated from the first side of the circuit board. The same circuit board component can also be heated from the opposing second side of the circuit board. Heating the circuit board component from the opposing second side of the circuit board is accomplished by channeling heated gas towards vias in the circuit board. The vias comprise conductor-filled channels through the circuit board. The vias have opposing apertures on the first and second side of the circuit board. Apertures located on the first side of the circuit board can be adjacent the circuit board component and, particularly, adjacent connections between the circuit board and the circuit board component.

In order to heat the circuit board component using vias, a flow of heated gas is channeled towards the vias. This hot gas heats the vias and thereby conducts heat towards the circuit board component. The gas is heated to a predetermined temperature sufficient to reflow connections between the first side of the circuit board and the circuit board component. The heated gas can be channeled towards selected vias. These selected vias are vias having apertures corresponding to predetermined areas of the circuit board component or to specific connections between the first side of the circuit board and the circuit board component. For example, the predetermined areas or specific connections can be those areas or connections where there is a temperature differential greater than approximately 10 degrees Celsius compared to other areas or connections across the circuit board component. By channeling heated gas towards the selected vias, the temperature of the predetermined areas or the specific connections can be increased and the temperature differential across the circuit board component may be controlled. For example, this method may be used to establish a difference in temperature between the circuit board component connections of less than 10 degrees Celsius. Directing heated gas towards selected vias can be accomplished by placing the second side of the circuit board on a supplemental heater (i.e., second heater described above), comprising a diffuser plate connected to a nozzle. The diffuser plate comprises openings corresponding to the selected vias in the circuit board. The diffuser plate is adapted to be positioned against the second side of the circuit board. The nozzle is adapted to channel heated gas through the diffuser plate openings. Once the diffuser plate is positioned against the second side of the circuit board and the diffuser plate opening and vias are aligned, heated gas is channeled through the diffuser plate openings towards the selected vias. Diffuser plates can be interchangeable to vary the number and pattern of diffuser plate openings to correspond to selected vias. The flow of heated gas can also be baffled through the diffuser plate to regulate the flow of heated gas towards selected vias. Once an approximately uniform temperature across the circuit board component is met and this temperature is sufficient to reflow the connections between the circuit board and the circuit board components, the circuit board component can be removed from the circuit board.

These, and other, aspects and objects of the present invention will be better appreciated and understood when considered in conjunction with the following description and the accompanying drawings. It should be understood, however, that the following description, while indicating embodiments of the present invention and numerous specific details thereof, is given by way of illustration and not of limitation. Many changes and modifications may be made within the scope of the present invention without departing from the spirit thereof, and the invention includes all such modifications.

### BRIEF DESCRIPTION OF THE DRAWINGS

The invention will be better understood from the following detailed description with reference to the drawings, in which:

FIG. 1 is a schematic representation of a rework system;

FIG. 2 is a schematic drawing of one embodiment of a rework system;

FIG. 3a is an exploded schematic drawing of one section of FIG. 2;

FIG. 3b is an exploded schematic drawing of one section of FIG. 3a;

FIG. 4 is a schematic perspective view drawing of one embodiment of the second heater 201 of FIG. 2;

FIGS. 5a-c are schematic drawings illustrating the diffuser plate patterning process;

FIG. 6 is a schematic drawing of another embodiment of the system of the present invention;

FIG. 7 is a schematic flow diagram of one embodiment of the method of the present invention;

FIG. 8 is a schematic flow diagram of the method process 708 of FIG. 7; and

FIG. 9 is a schematic flow diagram of another embodiment of the method of the present invention.

### DETAILED DESCRIPTION OF PREFERRED EMBODIMENTS OF THE INVENTION

The present invention is a method and system for reworking circuit boards. Specifically, it is a method and system that can be used to heat a circuit board component to an approximately uniform temperature across the circuit board component sufficient to reflow the connections between the circuit board component and the circuit. As stated above, BGA, CCGA, or other grid array circuit boards are often reworked by globally heating the entire circuit board and then locally heating the individual circuit board component with hot gas (e.g., air, nitrogen, etc.) and/or heating elements in order to reach the reflow temperature at the solder joints. As the individual circuit board component is heated, the temperature distribution across the component should also remain essentially uniform (e.g., within the 10 degrees Celsius). However, establishing and maintaining uniformity of temperature distribution can be difficult when using prior art methods of localized heating and the problem becomes worse as the package size increases.

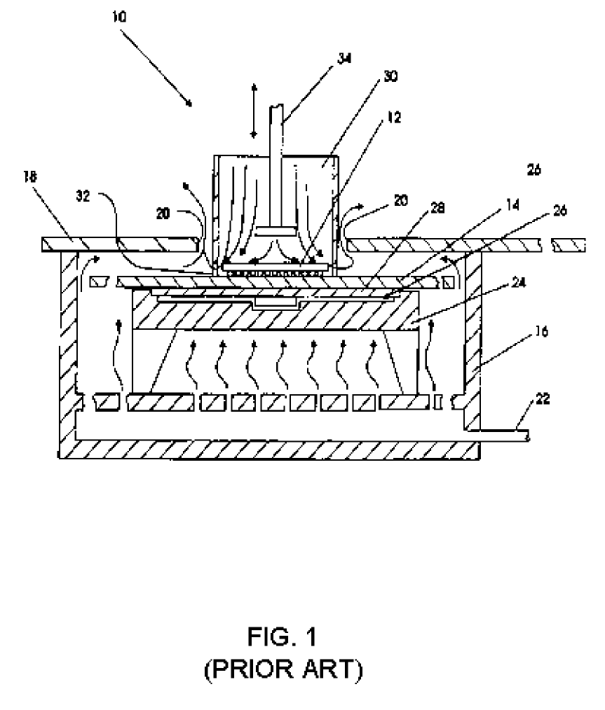

U.S. Pat. No. 5,735,450 issued to Heim et al. on Apr. 7, 1998 (incorporated herein by reference) discloses an exemplary prior art rework system for heating a board-mounted component. Referring to FIG. 1, this system discloses using a pre-heater 16 to globally heat a circuit board 14, locally heating an attached circuit board component 12 from above using hot gas heater 30, and locally heating the circuit board 14 beneath where the component 12 is attached using a heating element 26 and a conductive plate 28. Uniformity of temperature distribution is difficult to establish using such a prior art system because the hot gas focused over the component is directed towards the center of the component. Additionally, the supplemental bottom side heater inefficiently tries to heat the component from a distance. Thus, a temperature differential of up to or exceeding 20 degrees Celsius is often created between the center of the component and its corners.

Therefore, the embodiments of the method and system of the present invention were developed to provide an enhanced heating system for use on a circuit board (e.g., BGA or CCGA circuit boards) during a rework process. The enhanced heating system uses a supplemental heater which can be used in addition to a global pre-heater and another local heater that applies hot gas to the individual circuit board component from above the component. The supplemental heat is provided to establish and maintain uniformity of temperature distribution across the circuit board component. For example, the supplemental heat can be directed toward a particular section of the component (e.g., the corners of the component) to raise the temperature of that section to approximately the same temperature as rest of the component.

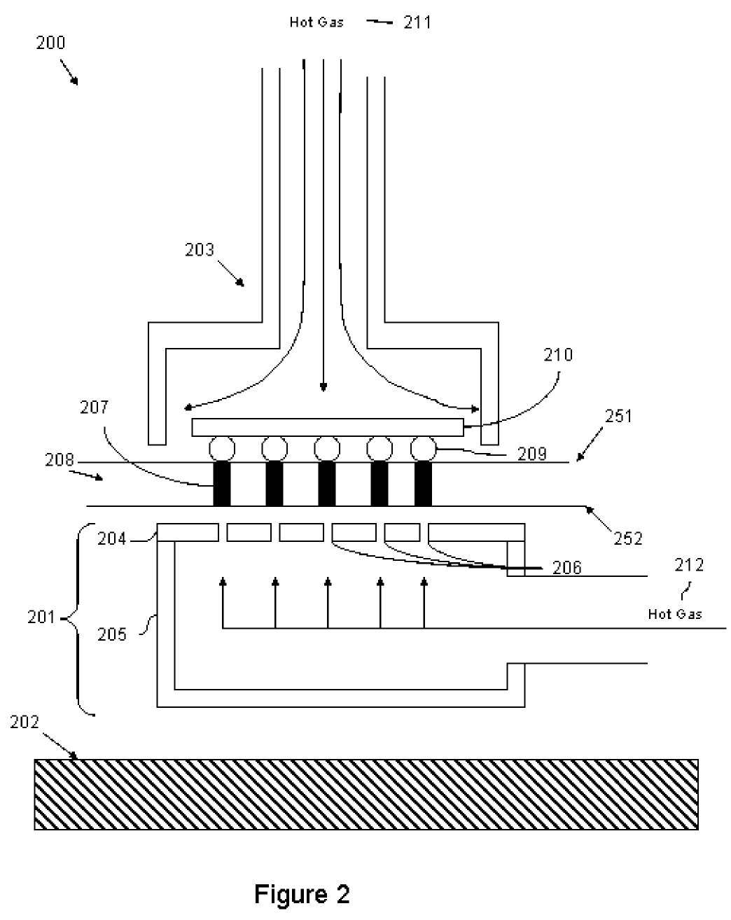

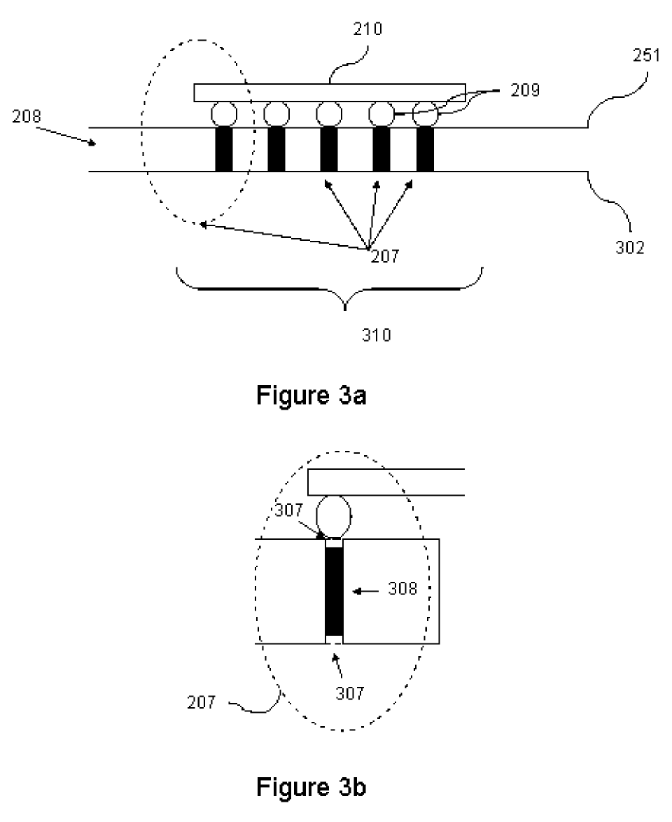

Referring to FIG. 2, an embodiment of the system 200 of the present invention for reworking a circuit board 208 can comprises three heaters (201, 202, and 203). A first heater 203 (e.g., a top side local gas heater) can be used to flow a first hot gas 211 (e.g., air, nitrogen, etc.) over a circuit board component 210 connected to the first side 251 of the circuit board from the first side 251 of the circuit board 208. A second heater 201 (e.g., a bottom side local gas heater) can be positioned on a second side 252 of the circuit board 208 in a component region 310 (see FIG. 3) opposite the circuit board component 210 and can channel a flow of hot gas 212 towards vias 207 in the circuit board 208 to conduct heat towards the circuit board component 210 from the second side 252 of the circuit board 208. A third heater 202 (e.g., pre-heater) can globally heat the circuit board 208. The system 200 of the present invention and, specifically, the second heater 201 takes advantage of via holes (i.e., vias 207) located on land grid array (LGA) circuit boards 208 adjacent the solder joints 209 (i.e., connections) connecting circuit board components 210 to the a first side 251 of circuit board 208. Hot gas 212 (e.g., air, nitrogen, etc.) is directed towards the vias 207 to rapidly and uniformly reflow the solder joints 209. This is accomplished by using the second heater 201.

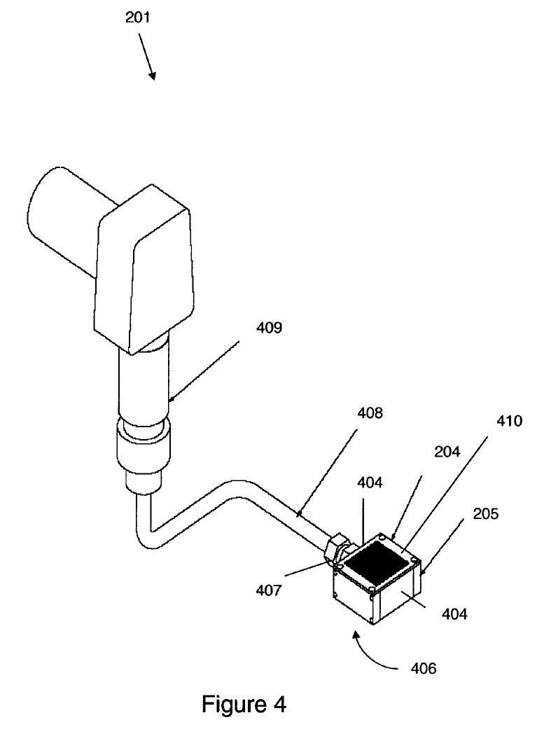

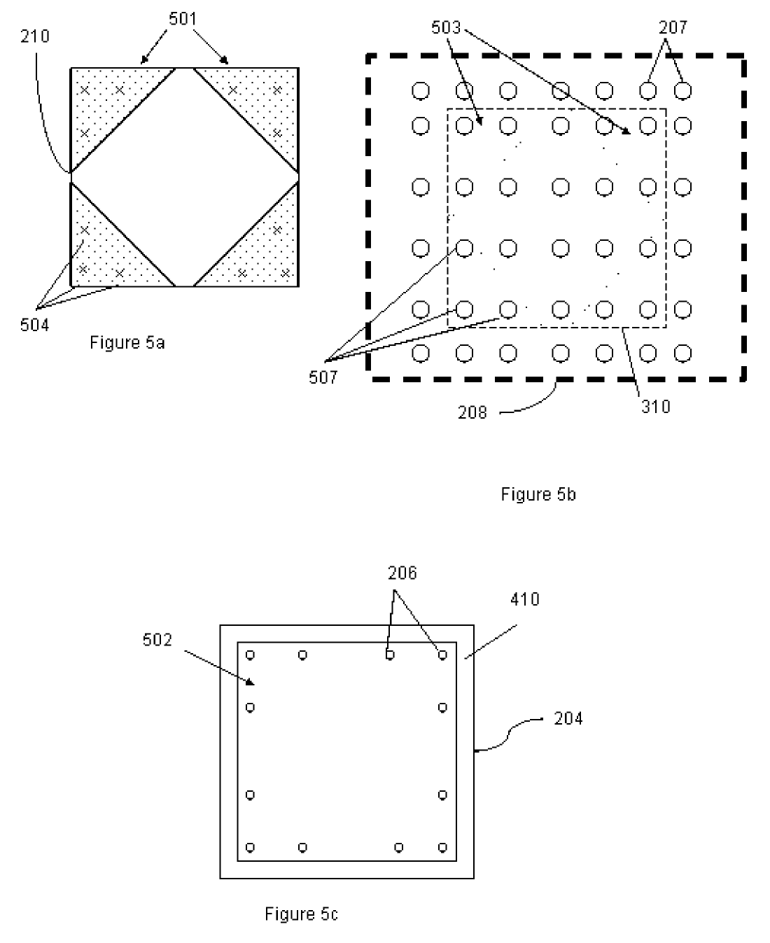

Referring in combination to FIGS. 2-4, the second heater 201 comprises a hot gas diffuser plate 204 mounted on top of a nozzle 205. A gas heating device 409 having a high velocity blower 409 (e.g., heat gun) heats a gas 212 to a predetermined temperature sufficient to reflow connections 209 between the circuit board component 210 and the circuit board 208. The heated gas 212 is piped through a gas conduit 408 into the nozzle 205 via a gas inlet 407 on a sidewall 404 of the nozzle 205. The nozzle 205 further comprises a flat supporting base 406 and additional sidewalls 404. The nozzle 205 is connected to the diffuser plate 204 opposite the flat base 406. The diffuser plate 204 comprises openings 206 corresponding to vias 207 on the circuit board 208. Specifically, the openings 206 on the diffuser plate comprise a pattern 502 of openings 206 that match and are aligned with vias 207 in the component region 310 of the circuit board 208 (see FIGS. 5a-c, discussed in further detail below). The diffuser plate openings 206 can be smaller in size relative to the openings of the vias 207 located on the circuit board 208 to ensure that the hot gas 212 is directed towards the via 207 and not over the entire outer surface of the second side 252 of the circuit board 208.

In operation, the circuit board 208 is set on the diffuser plate 204 such that the diffuser plate is positioned against the second side 252 of the circuit board 208 in the component region 310 opposite where the circuit board component 210 is connected on the first side 251 of the circuit board 208. The diffuser plate openings 206 are aligned with vias 207. The diffuser plate 204 and its frame 410 (which may be either connected to or integral to the diffuser plate 204) together can be larger in size relative to the circuit board component 210 being reworked. The nozzle 205 can also preferably be formed of a rigid structure (e.g., stainless steel) to provide a firm base during rework. Thus, the second heater 201 can provide a firm support for the circuit board 208 during rework and can prevent any bowing of the circuit board/card 208 during the rework process.

Referring to FIGS. 3a-b, the vias 207 comprise conductor-filled channels 308 through the circuit board 208. Each via channel 308 has opposing apertures 307 on the first and second sides 251, 252 of the circuit board 208. The apertures 307 located on the first side 251 of the circuit board are adjacent to the circuit board component 210 and, specifically, to connections 209 (e.g., solder joints) between the circuit board component 210 and the circuit board 208. A flow of heated gas 212 entering the nozzle 205 is channeled through the diffuser plate openings 206 towards the vias 207 which conduct heat towards the circuit board component 210.

Referring to FIGS. 5a-c, the number and pattern 502 of openings 206 on a diffuser plate 204 (as illustrated in FIG. 5c) can be changed to correspond to selected vias (e.g., 503, 507). Specifically, the diffuser plate pattern 502 can be changed to correspond with the pattern of the selected vias (e.g., 503, 507) in the component region 310. The selected vias can have apertures on the first side 251 of the circuit board 208 adjacent to predetermined areas (e.g., 501) of the circuit board component 210 or adjacent to specific connections 504 (e.g., solder joints) between the circuit board component 210 and the circuit board 208. For example, the predetermined areas 501 and specific connections 504 can be those areas or connections where there is a temperature differential greater than approximately 10 degrees Celsius compared to other areas or connections across the circuit board component 210. FIG. 5a illustrates an exemplary circuit board component 210 and, specifically, exemplary predetermined areas 501 (e.g., the corners of the circuit board component 210) or specified solder joints 504 (e.g., those solder joints located on the corners of the circuit board components) that might have a lower temperature relative to the rest of the circuit board component 210. FIG. 5b illustrates an exemplary circuit board 208 and the full pattern of vias 207 in the component region 310. FIG. 5b further illustrates the selected vias 503 or 507 that correspond to the predetermined areas 501 or the specified connections 504 of FIG. 5a, respectively. FIG. 5c illustrates an exemplary diffuser plate 204, having a frame 410 larger than the size of the circuit board component. The diffuser plate 204, as illustrated, comprises a pattern 502 of diffuser plate openings 206 that corresponds to the selected vias 507 and 503 of FIG. 5b. Thus, heated gas 212 can be channeled through the diffuser plate openings 206 towards selected vias (e.g., 507, 503) and the vias are heated and can conduct heat towards the predetermined areas 501 of the circuit board component 210 or towards specific connections 504 on the circuit board component 210 to control temperature distribution across the circuit board component 210.

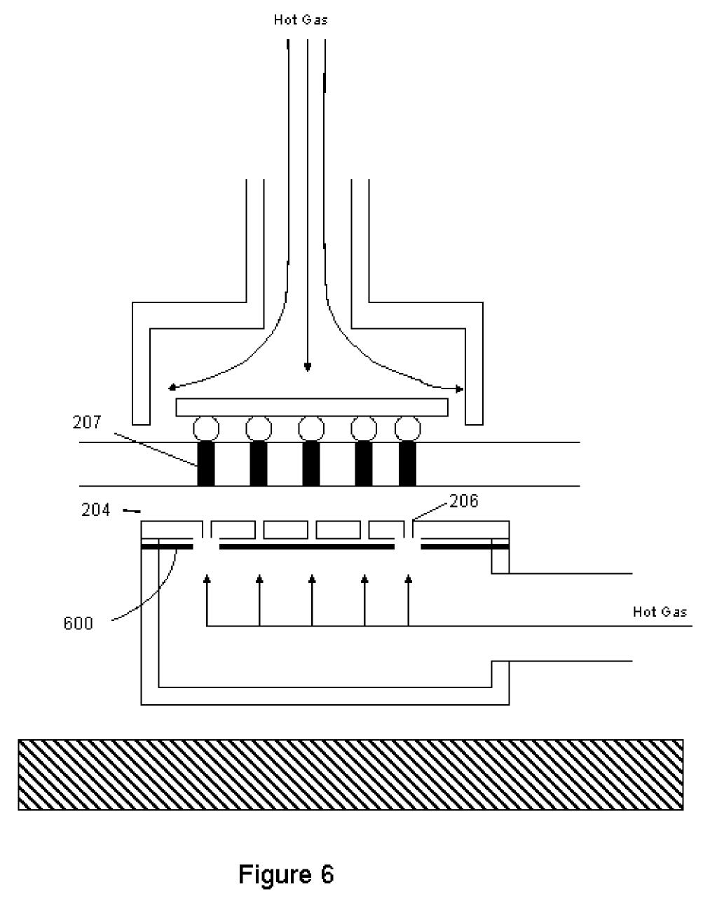

To direct the heated gas 212 towards the selected vias (e.g., 503, 507), the nozzle 205 can be configured to receive interchangeable diffuser plates 204 or can be configured with a baffle 600 (see FIG. 6). The interchangeable diffuser plates can be pre-drilled and used to vary the pattern 502 of diffuser plate openings on the second heater 201 such that the different diffuser plates comprise different numbers of openings and/or different patterns of openings corresponding to a number and pattern of selected vias (e.g., 503, 507). For example, the diffuser plate 204 can be easily replaced so that the diffuser plate pattern 502 of openings 206 corresponds to the full pattern of vias at the site itself 505, corresponds to vias in predetermined areas 501 of the site, or corresponds to vias for specific connections 504 on the site. The diffuser plate 204 may also be replaced to vary the size of the diffuser plate openings 206 (e.g., 1.27 mm, 1,0 mm, etc.). The openings 206 of the diffuser plate 204 can be matched precisely with the vias 207 of the rework site by using the alignment pin and tooling holes of a given circuit board 208, making the system 200 highly universal. Precisely matching the diffuser plate openings 206 with the vias 207 can prevent the hot gas 212 from simply heating the second side 252 of the circuit board 208, as disclosed by the prior art. Alternatively or in addition to the interchangeable diffuser plates 204, the second heater 201 can comprise a baffle 600 operably connected to the diffuser plate 204. The baffle 600 can be use to regulate the flow of the heated gas 212 through the diffuser plate openings 206 and towards the selected vias 507, 503. Channeling hot gas 212 in this manner creates a very uniform temperature distribution across the x, y and z axes of the component 210 being reworked and minimizes heat conduction through the circuit board 208. By maintaining this uniform temperature distribution across the component 210, distortion within the component 208 and circuit board 210 is minimized.

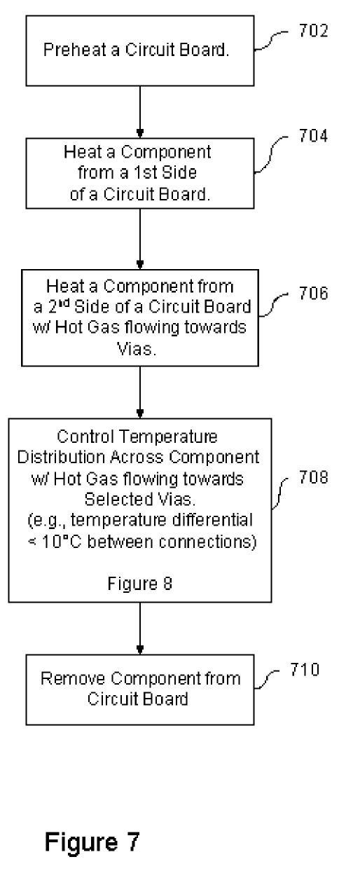

Referring to FIG. 7, an embodiment of a method of the present invention for reworking a circuit board can comprise three heating processes. A circuit board can be pre-heated 702. A circuit board component that is connected to a first side of the circuit board can be heated from the first side of the circuit board 704. The same circuit board component can be heated from the opposing second side of the circuit board by channeling gas towards vias in the circuit board 706. Vias comprise conductor-filled channels through the circuit board having opposing apertures on the first and second sides of the circuit board. Apertures located on the first side of the circuit board can be adjacent the circuit board component and, specifically, adjacent connections (e.g., solder joints) between the first side of the circuit board and the circuit board component. Heated gas heats the conductor-filled vias which, thereby, conduct heat towards the circuit board component.

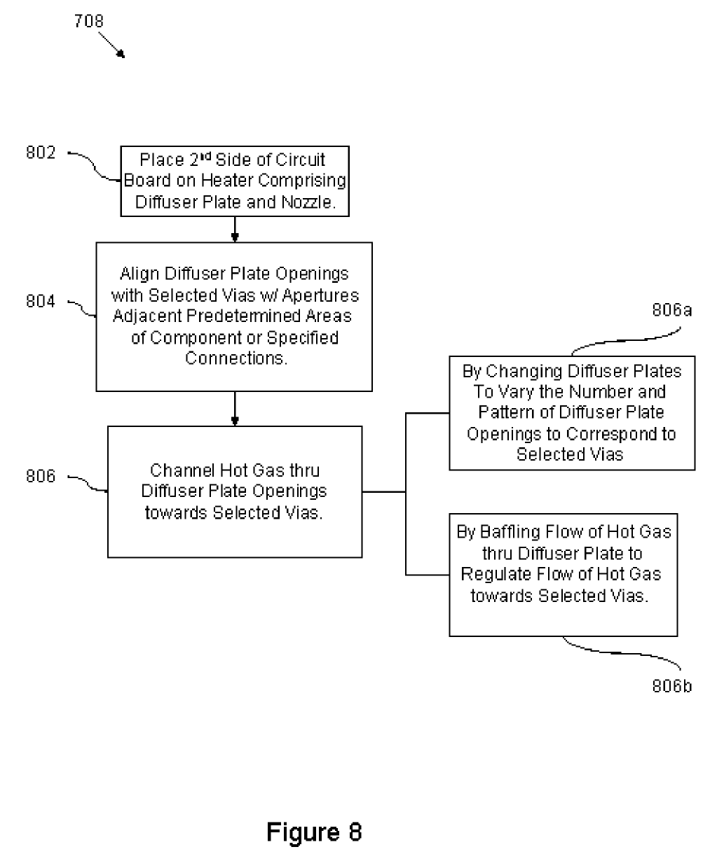

More particularly, in order to heat the circuit board component using the vias in the circuit board, a flow of heated gas is channeled towards the vias 706. These vias then conduct heat towards the circuit board component. The gas is heated to a predetermined temperature sufficient to reflow connections between the first side of the circuit board and the circuit board component. The heated gas can be channeled towards selected vias. These selected vias are vias having apertures corresponding to predetermined areas of the circuit board component or to specific connections between the first side of the circuit board and the circuit board component, where there is a temperature differential greater than approximately 10 degrees Celsius compared to other areas or connections across the circuit board component. By channeling heated gas towards the selected vias, the temperature of the predetermined areas or the specific connections can be increased and the temperature differential across the circuit board component may be controlled 708. For example, this method may be used to establish a difference in temperature between the circuit board component connections of less than 10 degrees Celsius. Referring also to FIG. 8, the method process of directing heated gas through selected vias can be accomplished by placing the component region of the second side of the circuit board on a supplemental heater 802. The supplemental heater can comprise a diffuser plate connected to a nozzle. The diffuser plate can comprise openings corresponding to the selected vias in the circuit board. The diffuser plate is adapted to be positioned against the second side of the circuit board. The nozzle is adapted to channel heated gas through the diffuser plate openings. Once the diffuser plate is positioned against the second side of the circuit board the diffuser plate openings and the selected vias are aligned 804, the heated gas is channeled through the diffuser plate openings towards the selected vias 806. Heated gas heats vias which conduct heat towards the predetermined areas of the circuit board component or the specific connections. The diffuser plates can be changed to vary the number and pattern of diffuser plate openings corresponding to vias, thereby determining the areas of the circuit board component towards to which heat is conducted 806a. The flow of heated gas can also be baffled through the diffuser plate to regulate the flow of heated gas towards selected vias 806b. Once an approximately uniform temperature across the circuit board component is met and this temperature is sufficient to reflow the connections between the circuit board and the circuit board component, the circuit board component can be removed from the circuit board 710.

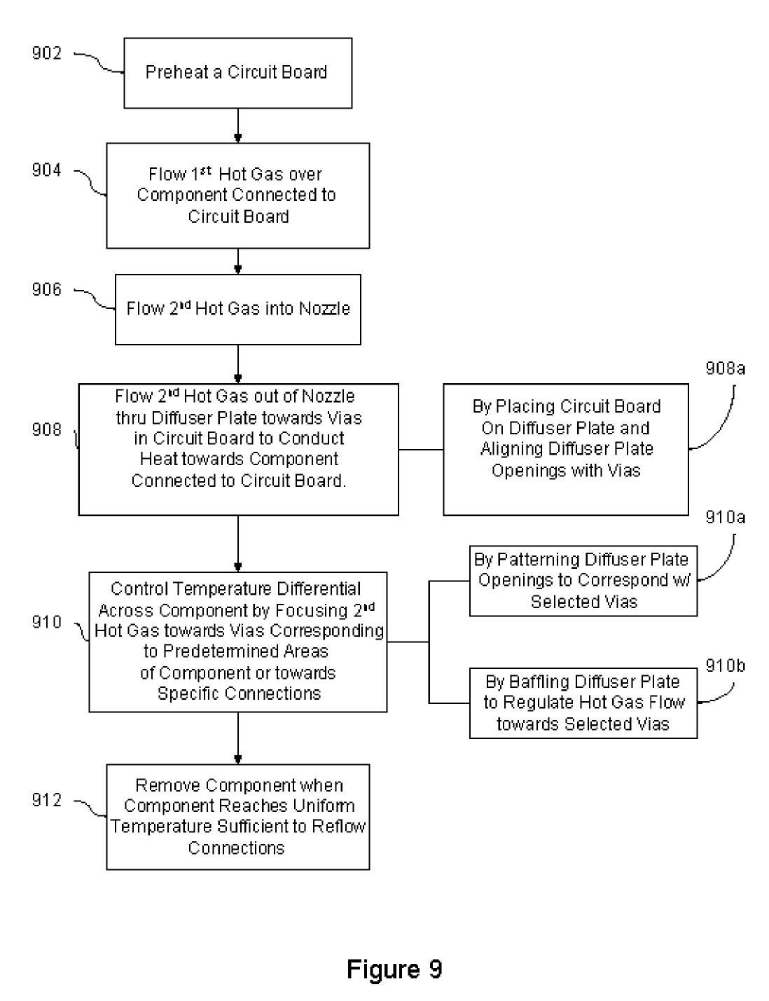

FIG. 9 illustrates another embodiment of the method of the present invention. Referring to FIG. 9, a circuit board is preheated 902. A first hot gas flows over a circuit board component connected to a first side of a circuit board 904. The first hot gas is sufficient to reflow connections between the circuit board and the circuit board component. A second hot gas flows into a nozzle 906 and out of a diffuser plate connected to the nozzle 908. The temperature of the second hot gas is also sufficient to reflow connections between the circuit board and the circuit board component. The diffuser plate comprises a plurality of diffuser plate openings corresponding to a plurality of vias on a circuit board. The vias comprise conductor-filled channels from a second side of the circuit board to a first side of the circuit board where a circuit board component is connected. The diffuser plate directs the second gas towards the vias, which are heated and thereby conduct heat towards the circuit board component 908. Flowing the hot gas through the diffuser plate and towards the vias can be accomplished by placing the second side of the circuit board on the diffuser plate and aligning the diffuser plate openings with the vias 908a.

The temperature differential across the circuit board component can be controlled in order to heat the circuit board to an approximately uniform temperature. This is accomplished by focusing the second gas towards selected vias. The selected vias comprise apertures adjacent to predetermined areas of the circuit board component or to specific connections (e.g., solder joints) between the circuit board component and the circuit board 910. For example, the predetermined areas or connections may be those areas or connections where there is a temperature differential greater than approximately 10 degrees Celsius compared to other areas or connections across the circuit board component. The process 910 of controlling the temperature differential across the circuit board component by focusing the second gas towards selected via corresponding to predetermined areas of the circuit board can be accomplished either by patterning the diffuser plate with diffuser plate openings that correspond to the selected vias 910a or by baffling the diffuser plate to regulate the flow of the second gas towards the selected vias 910b. In either process 910a or 910b, the second gas flowing out the diffuser plate is focused towards the selected vias and thus heat is conducted towards the predetermined areas or specific connections of the circuit board component to establish a uniform temperature across the circuit board component. Once a uniform temperature is established and that temperature is sufficient to reflow the connections between the circuit board and the circuit board component, the circuit board component can be removed 912.

Therefore, the system and method of the present invention takes advantage of the vias located on LGA circuit boards adjacent the solder joints to direct heat towards specific areas of a circuit board component to rapidly and uniformly reflow the solder joints and remove the component.

The present invention and the various features and advantageous details thereof are explained more fully with reference to the nonlimiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the present invention. The examples used herein are intended merely to facilitate an understanding of ways in which the invention may be practiced and to further enable those of skill in the art to practice the invention. Accordingly, the examples should not be construed as limiting the scope of the invention. While the invention has been described in terms of embodiments, those skilled in the art will recognize that the invention can be practiced with modification within the spirit and scope of the appended claims.

What is claimed is:

1. A circuit board rework system comprising:
a first heater adapted to be positioned on a first side of a circuit board over a circuit board component connected to said first side of said circuit board and to heat said circuit board component; and
a second heater adapted to be positioned on a component region of a second side of said circuit board and to heat a plurality of vias in said component region;
wherein said component region of said second side of said circuit board is opposite said circuit board component connected to said first side of said circuit board; and
wherein said second heater comprises a plurality of openings corresponding to said plurality of vias.

2. The system of claim 1, wherein each of said vias comprises a conductor-filled channel having a first aperture on said first side of said circuit board adjacent said circuit board component and an opposing second aperture on said second side of said circuit board in said component region.

3. The system of claim 1, wherein said plurality of openings are adapted to direct a channel of heated gas towards said plurality of vias;
wherein said heated gas is a predetermined temperature sufficient to reflow connections between said first side of said circuit board and said circuit board component; and
wherein said vias conduct heat from said heated gas towards said circuit board component.

4. The system according to claim 3, wherein said second heater comprises a plurality of openings corresponding to selected vias;
wherein said selected vias comprise said vias having a first via aperture adjacent to at least one of a predetermined area of said circuit board component and a specific solder connection between said circuit board component and said first side of said circuit board; and
wherein said circuit board component is connected to said first side of said circuit board by a plurality of solder connections.

5. The system according to claim 4, wherein the number and pattern of said plurality openings is adapted to correspond with said selected vias.

6. The system according to claim 4, wherein said second heater further comprises a diffuser plate and wherein said diffuser plate is adapted to be positioned against said component region and comprises said plurality of openings.

7. The system according to claim 6, wherein said diffuser plate comprises interchangeable diffuser plates.

8. The system according to claim 7, wherein said interchangeable diffuser plates comprise at least one of different numbers and different patterns of said plurality of openings corresponding to said selected vias.

9. The system according to claim 1, further comprising a third heater positioned to globally heat said circuit board.

10. A circuit board rework system comprising:
a first heater adapted to be positioned on a first side of a circuit board over a circuit board component connected to said first side of said circuit board and to heat said circuit board component; and
a second heater adapted to be positioned on a component region of a second side of said circuit board and to heat a plurality of vias in said component region; and
a third heater positioned to globally heat said circuit board;
wherein said component region of said second side of said circuit board is opposite said circuit board component connected to said first side of said circuit board; and
wherein said second heater comprises a plurality of openings corresponding to said plurality of vias.

11. The system of claim 10, wherein each of said vias comprises a conductor-filled channel having a first aperture on said first side of said circuit board adjacent said circuit board component and an opposing second aperture on said second side of said circuit board in said component region.

12. The system of claim 10, wherein said plurality of openings are adapted to direct a channel of heated gas towards said plurality of vias;
wherein said heated gas is a predetermined temperature sufficient to reflow connections between said first side of said circuit board and said circuit board component; and
wherein said vias conduct heat from said heated gas towards said circuit board component.

13. The system according to claim 12, wherein said second heater comprises a plurality of openings corresponding to selected vias;
wherein said selected vias comprise said vias having a first via aperture adjacent to at least one of a predetermined area of said circuit board component and a specific solder connection between said circuit board component and said first side of said circuit board; and
wherein said circuit board component is connected to said first side of said circuit board by a plurality of solder connections.

14. The system according to claim 13, wherein the number and pattern of said plurality openings is adapted to correspond with said selected vias.

15. The system according to claim 13, wherein said second heater further comprises a diffuser plate and wherein said diffuser plate is adapted to be positioned against said component region and comprises said plurality of openings.

16. The system according to claim 15, wherein said diffuser plate comprises interchangeable diffuser plates.

17. The system according to claim 16, wherein said interchangeable diffuser plates comprise at least one of different numbers and different patterns of said plurality of openings corresponding to said selected vias.

18. A method of reworking a circuit board, said method comprising:
heating a circuit board component that is connected to a first side of said circuit board by directing heat toward said first side of said circuit board; and
heating said circuit board component from an opposing second side of said circuit board by flowing heated gas through a pattern of openings on a heater, wherein said openings correspond to vias in a component region of said second side of said circuit board.

19. The method according to claim 18, wherein said process of flowing heated gas towards vias in a component region of said circuit board comprises aligning said pattern of openings on said heater with said vias in said component region.

20. The method according to claim 18, wherein said process of flowing heated gas towards vias in a component region of said circuit board further comprises selecting said pattern of openings on said heater to correspond to said vias.

21. The method of claim 18, further comprising changing interchangeable diffuser plates on said heater, wherein said interchangeable diffuser plates comprise openings having different patterns corresponding to different patterns of said vias.

22. The method of claim 19, further comprising preheating said circuit board.

23. A method of reworking a circuit board, said method comprising:
preheating said circuit board;
heating a circuit board component that is connected to a first side of said circuit board by directing heat toward said first side of said circuit board; and
heating said circuit board component from an opposing second side of said circuit board by flowing heated gas through a pattern of openings on a heater, wherein said openings correspond to vias in a component region of said second side of said circuit board.

24. The method according to claim 23, wherein said process of flowing heated gas towards vias in a component region of said circuit board comprises aligning said pattern of openings on said heater with said vias in said component region.

25. The method according to claim 23, wherein said process of flowing heated gas towards vias in a component region of said circuit board further comprises selecting said pattern of openings on said heater to correspond to a pattern of said vias.

26. The method of claim 23, further comprising changing interchangeable diffuser plates on said heater, wherein said interchangeable diffuser plates comprise openings having different patterns corresponding to different patterns of said vias.
